(19) United States
(12) Patent Application Publication
(10) Pub. No.: US 2013/0162101 A1
(43) Pub. Date: Jun. 27, 2013

(54) DIELECTRIC SINTERED BODY, METHOD FOR MANUFACTURING SAME, AND DIELECTRIC RESONATOR

(71) Applicants: Satoru Fujita, Ise-shi (JP); Yuki Kasuya, Ise-shi (JP)

(72) Inventors: Satoru Fujita, Ise-shi (JP); Yuki Kasuya, Ise-shi (JP)

(73) Assignee: NGK SPARK PLUG CO., LTD., Nagoya-shi, Aichi (JP)

(21) Appl. No.: 13/820,374

(22) PCT Filed: Sep. 2, 2011
(86) PCT No.: PCT/JP2011/070060

§ 371 Date: Mar. 1, 2013

(30) Foreign Application Priority Data
Sep. 2, 2010 (JP) 2010-196853

(51) Int. Cl. H01L 41/18; C04B 35/48

(52) U.S. Cl. CPC H01L 41/18; C04B 35/48
USPC 310/311; 501/135; 264/661

(57) ABSTRACT

A dielectric sintered body of the present invention contains Ba, Nb, and at least one of Zn and Co, as main components, and K and Ta as subcomponents. The ratio A of the peak intensity p2 of the (111) plane peak to the peak intensity p1 of the (310) plane peak in an X-ray diffraction measurement is 0.9 to 1.5. The half bandwidth C of the (111) plane peak ranges from 0.12 to 0.22°. The d-value D of the (111) plane peak ranges from 2.363 to 2.371. The dielectric sintered body has a Perovskite structure.

### CROSS REFERENCE TO RELATED APPLICATIONS

This international application claims priority to Japanese patent application No. 2010-196853 filed Sep. 2, 2010, the entire contents of which are hereby incorporated by reference.

### TECHNICAL FIELD

The present invention relates to dielectric sintered bodies applicable to, for example, dielectric resonators, dielectric filters, dielectric antennas, and dielectric substrates. The present invention also relates to methods for manufacturing such dielectric sintered bodies, and to dielectric resonators.

### BACKGROUND ART

Dielectric sintered bodies of various compositions have been studied for use in high-frequency regions such as microwaves and milliwaves. Among such dielectric sintered bodies, those based on BaZnCoNb (hereinafter, “BZCN”; see Patent Documents 1 and 2) have excellent stability because of their relatively large Q values (quality coefficient under no load), moderately large relative permittivities, and small resonant frequency temperature coefficients.

### PRIOR ART DOCUMENTS

### Patent Documents

Patent Document 1: JP-A-2003-201177

Patent Document 2: JP-A-2004-315330

### SUMMARY OF THE INVENTION

### Problems that the Invention is to Solve

However, the Q values of the BZCN-based dielectric sintered bodies of the related art greatly vary from one body to the next, and such dielectric sintered bodies lack stability in industrial production.

The present invention has been made under these circumstances, and it is an object of the present invention to provide a dielectric sintered body that has large Q values with small Q-value variation, a method for manufacturing same, and a dielectric resonator.

### Means for Solving the Problems

A dielectric sintered body of the present invention contains Ba, Nb, and at least one of Zn and Co, as main components, and K and Ta as subcomponents, the ratio A of the peak intensity p2 of the (111) plane peak to the peak intensity p1 of the (310) plane peak in an X-ray diffraction measurement being 0.9 to 1.5, the half bandwidth C of the (111) plane peak ranging from 0.12 to 0.22°, the d-value D of the (111) plane peak ranging from 2.363 to 2.371, and the dielectric sintered body having a Perovskite structure.

In the dielectric sintered body of the present invention, the peak intensity ratio A is 0.9 to 1.5; therefore, the Q value is large and the Q-value variation is small.

Further, in the dielectric sintered body of the present invention, the half bandwidth C of the (111) plane peak in an X-ray diffraction measurement ranges from 0.12 to 0.22°; therefore, crystallization proceeds and the Q value improves. Crystallization does not proceed and the Q value decreases, when the half bandwidth exceeds 0.22°, in other words, when the half bandwidth is wide. On the other hand, when the half bandwidth is below 0.12°, in other words, when the half bandwidth is too narrow, crystallization proceeds in excess, and the grain boundary plane becomes an influence, and the Q value lowers.

Further, in the dielectric sintered body of the present invention, the d-value D of the (111) plane peak in an X-ray diffraction measurement is 2.363 to 2.371; therefore, the atoms in the crystal lattice are orderly arranged, and the Q value improves. When the d-value D is below 2.363, some of the atoms break free of the crystal lattice, in other words, the arrangement becomes wavy, with the result that the lattice strains, and the Q value lowers. On the other hand, when the d-value D is above 2.371, the arrangement becomes nonuniform, and crystallization does not proceed, with the result that loosening occurs, and the Q value lowers. The unit of d-value D is Å.

Further, because the dielectric sintered body of the present invention contains K and Ta, the Q value is larger than that of a dielectric sintered body that does not contain K and Ta. Further, the Q value is far greater than that of a dielectric sintered body that does not contain these elements, even when the K and Ta contents are small.

Further, the dielectric sintered body of the present invention contains at least one of Zn and Co. Varying the proportions of the Zn and Co contents enables the Q value and an absolute value of τf to be selected from wide ranges. Particularly, the Q value can be greatly increased by increasing the Zn content. Specifically, the Q value shows a peak when the proportions of the Zn and Co contents are varied, and varies unpredictably in a manner different from the behaviors of the relative permittivity εr and the absolute value of τf. Further, increasing the Zn content can simultaneously increase the Q value and εr, and decrease the absolute value of τf.

Further, because the dielectric sintered body of the present invention has a Perovskite structure, high Q values can be obtained. X-ray diffraction reveals no individual peaks from the BaZnNb-based composition, the BaCoNb-based composition, or the KTa-based composition attributable to the constituting elements; instead, a single solid-solution peak distribution appears. The peak distribution resembles the peak distribution of the BaZnNb-based composition, and it can be determined that the dielectric sintered body of the present invention has a Perovskite structure of the BaZnNb-based composition.

The dielectric sintered body of the present invention preferably contains a Ba₅Nb₄O₁₅ crystalline phase. The presence of the Ba₅Nb₄O₁₅ crystalline phase can be confirmed by X-ray diffraction measurement. The Ba₅Nb₄O₁₅ crystalline phase can be confirmed in the vicinity of 2θ=29.5°. The Ba₅Nb₄O₁₅ crystalline phase is a subcrystalline phase observed when the Perovskite crystal lattice is orderly arrayed. The presence of the Ba₅Nb₄O₁₅ crystalline phase can be used as a criterion for determining whether the Perovskite structure is orderly arrayed.

The dielectric sintered body of the present invention preferably also contains zirconium oxide. Containing zirconium oxide improves the sintering stability, and further increases the Q value. The zirconium oxide content is preferably less than 0.3 weight parts (a zirconium oxide content of less than 0.3 wt %) with respect to 100 weight parts of the part represented by the composition formula above.

Preferably, the zirconium oxide exists at the crystal grain boundary plane of the dielectric sintered body. Particularly preferably, the zirconium oxide is omnipresent at the crystal grain boundary plane of the dielectric sintered body at a higher concentration than in other regions. The presence of the zirconium oxide at the crystal grain boundary plane makes it possible to move the substances with less heat quantity, and to easily precipitate the Ba₅Nb₄O₁₅ crystalline phase (a superlattice structure can be obtained more easily). As the result, high Q values are obtained.

Preferably, the dielectric sintered body of the present invention contains K, Ba, Nb, and Ta, and at least one of Zn and Co as constituting elements, and the composition ratio of the constituting elements substantially satisfies the composition formula: (100−a)[Baᵤ{(ZnᵥCo₁₋ᵥ)_{w}Nbₓ}O_{δ1}]−a[K_{y}Ta_{z}O_{δ2}] (0.5≦a≦25, 0.98≦u≦1.03, 0≦v≦1, 0.274≦w≦0.374, 0.646≦x≦0.696, 0.5≦y≦2.5, 0.8≦z≦1.2).

In this case, because the dielectric sintered body of the present invention contains K and Ta, the Q value is larger than that of a dielectric sintered body that does not contain these elements. Further, the Q value is far greater than that of a dielectric sintered body that does not contain these elements, even when the K and Ta contents are small. Further, the Q value shows an unpredictable, unexpected behavior, specifically a peak (maximum value) is observed in the vicinity of a=2.5.

Further, because the dielectric sintered body of the present invention contains K and Ta, the absolute value of the resonant frequency temperature coefficient (hereinafter, also referred to simply as “τf”) is small. Further, the absolute value of τf can be configured far smaller than that of a dielectric sintered body that does not contain these elements, even when the K and Ta contents are small. Further, τf shows an unpredictable, unexpected behavior; specifically, a peak (minimum value) is observed in the vicinity of a=5. Further, including K and Ta may lower the sintering temperature for production of the dielectric sintered body.

In the foregoing composition formula, the variable a representing the proportions of the K and Ta contents is 0.5≦a≦25. The foregoing effects can be sufficiently obtained when the variable a is equal to or greater than 0.5. On the other hand, when the variable a is equal to or less than 25, it becomes easier to maintain the shape of the molding during the sintering process, and the dielectric sintered body can easily be obtained. The value a is not particularly limited as long as it falls within the foregoing range. However, in terms of obtaining the foregoing effects, the value a is preferably 1≦a≦20, more preferably 1≦a≦10, and further preferably 2≦a≦8.

In the composition formula above, y is 0.5≦y≦2.5 (preferably, 1.0≦y≦2.0). Because the variable y is equal to or greater than 0.5, the dielectric sintered body can be sufficiently sintered during its manufacturing process. Further, with the variable y falling in this range, the product of the Q value and the resonant frequency (hereinafter, “f×Q value”) can configured with a sufficiently large value. Further, z is 0.8≦z≦1.2. A range where z is 0.9≦z≦1.1 is preferable since the f×Q value is particularly large in this range.

Further, the dielectric sintered body of the present invention contains at least one of Zn and Co. Varying the proportions of the Zn and Co contents enables the Q value and an absolute value of τf to be selected from wide ranges. Particularly, the Q value can be greatly increased by increasing the Zn content. Specifically, the Q value shows a peak when the proportions of the Zn and Co contents are varied, and varies unpredictably in a manner different from the behaviors of the relative permittivity εr and the absolute value of τf. Further, increasing the Zn content can simultaneously increase the Q value and εr, and decrease the absolute value of τf.

The variable v representing the proportion of the Zn content may be varied within the range 0≦v≦1. The value v is not particularly limited, and is preferably 0.3≦v≦1 so as to improve all the dielectric characteristics. Further preferably, v is 0.4≦v≦0.8 so as to maintain a large Q value. Particularly preferably, v is 0.4≦v≦0.75 so as to obtain desirable dielectric characteristics with a good balance of a large Q value and a small τf absolute value. The variable 1−v representing the proportion of the Co content may similarly be varied within the range 0≦1−v≦1.

The variable u is 0.98≦u≦1.03, preferably 0.99≦u≦1.02. The f×Q value can have a sufficiently large value with the value u falling in these ranges. Further, with the variable u being equal to or less than 1.03, the dielectric sintered body can be sufficiently sintered during its manufacturing process. The variable w is 0.274≦w≦0.374, preferably 0.294≦w≦0.354. The f×Q value can be a sufficiently large value with the value w falling in these ranges. The variable x is 0.646≦x≦0.696, preferably 0.656≦x≦0.686. The f×Q value can be a sufficiently large value with the value x falling in these ranges.

The values of δ1 and δ2 are typically equivalent values of the contained metals. These values are not particularly limited, as long as the desired dielectric characteristics are not lost. For example, δ1 may be 2.9≦δ1≦3.1, and β2 may be 2.5≦δ2≦4.

In the dielectric sintered body of the present invention, the composition formula is represented by two terms: the term Baᵤ{(ZnᵥCo₁₋ᵥ)_{w}Nbₓ}O_{δ1} (hereinafter, simply “BZCN-based composition”) , and the term “K_{y}Ta_{z}O_{δ2}” (hereinafter, simply “KTa-based composition”). However, in the actual dielectric sintered body, the BZCN-based composition and the KTa-based composition form a single solid solution composition, as evidenced by the absence of the diffraction peak (31.69°) of the KTa-based composition alone in an X-ray diffraction measurement.

It is therefore possible in the dielectric sintered body of the present invention to obtain a large Q value and a small τf absolute value unattainable with the dielectric sintered body of solely the BZCN-based composition, and these and other dielectric characteristics can be obtained in good balance.

The dielectric sintered body of the present invention may also contain, for example, Mn or W, in addition to the foregoing components. In the case of Mn, the Mn content in terms of MnO₂ is 0.02 to 3 weight parts, preferably 0.02 to 2.5 weight parts, further preferably 0.02 to 2 weight parts, particularly preferably 0.02 to 1.5 weight parts, most preferably 0.05 to 1.5 weight parts with respect to 100 weight parts of the part represented by the composition formula (100−a)[Baᵤ{(ZnᵥCo₁₋ᵥ)_{w}Nbₓ}O_{δ1}]−a[K_{y}Ta_{z}O_{δ2}]. In the case of W, the W content in terms of WO₃ is 0.02 to 4.5 weight parts, preferably 0.02 to 4 weight parts, further preferably 0.02 to 3.5 weight parts, particularly preferably 0.02 to 3 weight parts, most preferably 0.03 to 2 weight parts. The Mn or W content (in terms of an oxide) is preferably 0.02 weight parts or more, because it can suppress a retention rate of the Q value from being lowered at high temperatures, and maintain more desirable Q values. The Mn content (in terms of an oxide) is preferably 3 weight parts or less, or the W content (in terms of an oxide) is preferably 4.5 weight parts or less, because it can prevent the Q value from being lowered at room temperature and at high temperatures, and can make the τf absolute value smaller to maintain more desirable dielectric characteristics.

The Mn and W are present in the dielectric sintered body by being added typically in the form of oxides such as MnO₂ and WO₃. However, the forms of Mn and W are not limited to oxides, as long as these elements can be contained in the dielectric sintered body. For example, Mn and W may be added in the form of salts, halides, and alkoxides.

In the dielectric sintered body of the present invention, it is preferable that the composition containing K, Ba, Nb, and Ta, and at least one of Zn and Co substantially satisfies the following specific composition formula (an example of the composition formula above).

Specific composition formula:

98.8Ba_{1.02}(ZnᵥCo₍₁₋ᵥ₎)_{0.308}Nb_{0.692}O_{δ1}−1.2K_{1.5}TaO_{δ2}

The dielectric sintered body can have an even larger Q value and even smaller Q-value variation by substantially satisfying this specific composition formula.

Preferably, the specific gravity of the dielectric sintered body of the present invention is, for example, 6.2 or less, or 6.25 or more. The dielectric sintered body can have an even larger Q value and even smaller Q-value variation when the specific gravity falls in this range.

The volume of the dielectric sintered body of the present invention is preferably 15 cm³ or less. Even larger Q values can be obtained in this volume range. Further, with the dielectric sintered body volume falling in this range, higher Q values can be obtained without adding zirconium oxide (or when only small amounts of zirconium oxide are added), as compared with the case where the volume of the dielectric sintered body volume falls outside of the foregoing range.

The dielectric sintered body of the present invention can be obtained, for example, by adding zirconium oxide after calcining the raw material, and then performing sintering. The raw material may be, for example, a mixture of the foregoing constituting elements prepared in the composition ratio that substantially satisfies the composition formula above (for example, the specific composition formula).

Preferably, the zirconium oxide is added after the calcination of other raw materials (including Ba, Nb, Zn, and Co). In this way, it is possible to suppress a phenomenon in which a reaction between Zr and Nb occurs during the calcination, resulting in a composition shift which would lower the Q value. Note that this phenomenon may occur when the calcination is performed after mixing the zirconium oxide with the other raw materials.

The zirconium oxide is added preferably in less than 0.3 weight parts (a zirconium oxide content of less than 0.3 wt %) with respect to 100 weight parts of the part represented by the foregoing composition formula. This configuration can improve the sintering stability, which can further increase the Q value.

The sintering temperature in the sintering preferably ranges from 1,375 to 1,600 degrees Celsius, particularly preferably 1,425 to 1,575 degrees Celsius. The dielectric sintered body can have more desirable dielectric characteristics in these sintering temperature ranges. The hold time in the sintering preferably ranges from 2 to 10 hours. This hold time range is effective for improving the sintering stability and making the characteristic variation smaller.

In the dielectric sintered body of the present invention, the peak intensity ratio A can easily be set within the range of from 0.9 to 1.5 by adjusting one of or both of the sintering temperature and the hold time of the sintering.

Provided that the hold time is constant, the sintering temperature and the peak intensity ratio A have the following relationship. The peak intensity ratio A gradually increases as the sintering temperature increases up to a predetermined temperature. Above the predetermined temperature, the peak intensity ratio A gradually decreases as the sintering temperature increases.

Further, provided that the sintering temperature is constant, the hold time and the peak intensity ratio A have the following relationship. The peak intensity ratio A gradually increases as the hold time increases up to a predetermined hold time. Above the predetermined hold time, the peak intensity ratio A gradually decreases as the hold time increases.

The peak intensity ratio A can easily be set to any value in the range of 0.9 to 1.5 by adjusting one of or both of the sintering temperature and the hold time according to the relationship between the sintering temperature and the peak intensity ratio A, and the relationship between the hold time and the peak intensity ratio A.

The calcining temperature preferably ranges from 1,000 to 1,200 degrees Celsius. Desirable moldability and high f×Q values can be obtained in this calcining temperature range.

Note that the dielectric characteristics εr and τf are values as measured in the TE₀₁₁ mode, and the f×Q value is a value as measured in the TE₀₁δ mode described later. The reason the f×Q value is used is that the calculation of an f×Q value makes it possible to lessen the influence of the resonant frequency fluctuation, which unavoidably occurs in each measurement in dielectric characteristics measurement. This enables more accurate evaluations of dielectric loss.

The dielectric resonator of the present invention can be produced from the dielectric sintered body. The dielectric resonator of the present invention has a large Q value and small Q-value variation.

### BRIEF DESCRIPTION OF THE DRAWINGS

FIG. 1 is a graph representing the result of the X-ray diffraction measurement of a dielectric sintered body in Embodiment 1.

FIG. 2 is a photograph representing a SEM image of a dielectric sintered body of Embodiment 3.

FIG. 3 is a graph representing the result of the X-ray diffraction measurement of a dielectric sintered body in Experiment Example.

### MODE FOR CARRYING OUT THE INVENTION

Embodiments of the present invention are described below.

### Embodiment 1

### 1. Production of Dielectric Sintered Body

Dielectric sintered bodies were produced as follows.
(i) Barium carbonate, zinc oxide, cobalt oxide, niobium oxide, potassium carbonate, and tantalum oxide were each weighed to make the K, Ba, Nb, Ta, Zn, and Co composition ratio satisfy the specific composition formula below. These were then milled and mixed using a vibration mill.

### Specific Composition Formula:

98.8Ba_{1.02}(ZnᵥCo₍₁₋ᵥ₎)_{0.308}Nb_{0.692}O_{δ1}−1.2K_{1.5}TaO_{δ2}

In the specific composition formula, v is 0.40, and δ1 and δ2 are the equivalent values of the contained metals.
(ii) The powder after the milling and mixing process was calcined at 1,100 degrees Celsius for 4 hours.
(iii) The powder after the calcination was milled and mixed using a Trommel mill after adding water, a binder, and zirconium oxide. The water, the binder, and the zirconium oxide were added in 40 weight parts, 2 weight parts, and 0.1 weight parts, respectively, with respect to 100 weight parts of the powder after the calcination. A PVA was used as the binder.
(iv) The powder was granulated with a spray dryer, and the granulated powder was molded into the shape of a resonator (outer diameter 41 mm, inner diameter 23 mm, thickness 17 mm; hollow cylindrical shape), using a press machine.
(v) After being defatted at 500 degrees Celsius for 8 hours, the molding was subjected to sintering at the sintering temperatures and the hold times presented in Table 1 under the atmosphere to obtain a sintered body (dielectric sintered body).

The sintering was performed under 12 different sintering temperature and hold time conditions (Nos. 1 to 12 in Table 1). The dielectric sintered body was produced in each condition. A total of six dielectric sintered bodies (n) were produced in each condition. Further, evaluation was performed for each of the 12 dielectric sintered bodies, as will be described later. The maximum value, the minimum value, and the variation (described later) are values at n=6.

TABLE 1

| | | | | | | | f × Q value (GHz) | | | | |
|---|---|---|---|---|---|---|---|---|---|---|---|
| | | | | | | | | | | Maximum | |
| | Sintering | Hold | | Half | | | | | | value − | |
| | temperature | time | Intensity | bandwidth C | d-Value D | Specific | Mean | Maximum | Minimum | minimum | |
| No | (° C.) | (hr) | ratio A | (°) | (Å) | Gravity B | value | value | value | value | Variation |
| 1 | 1490 | 6 | 1.34 | 0.14 | 2.365 | 6.27 | 68550 | 69040 | 67880 | 1160 | 1.69 |
| 2 | 1510 | 2 | 1.47 | 0.15 | 2.363 | 6.28 | 68010 | 68470 | 67520 | 950 | 1.40 |
| 3 | 1510 | 4 | 1.02 | 0.19 | 2.365 | 6.27 | 69020 | 69370 | 68130 | 1240 | 1.80 |
| 4 | 1510 | 6 | 0.91 | 0.20 | 2.365 | 6.26 | 69610 | 70300 | 68540 | 1760 | 2.53 |
| *5 | 1535 | 2 | 0.85 | 0.25 | 2.367 | 6.24 | 58340 | 59700 | 57180 | 2520 | 4.32 |
| *6 | 1535 | 3 | 2.46 | 0.15 | 2.360 | 6.23 | 67110 | 68030 | 66460 | 1570 | 2.34 |
| *7 | 1535 | 4 | 2.72 | 0.14 | 2.363 | 6.22 | 63850 | 65450 | 60900 | 4550 | 7.13 |
| *8 | 1535 | 5 | 2.85 | 0.14 | 2.364 | 6.21 | 65640 | 66370 | 65190 | 1180 | 1.80 |
| 9 | 1535 | 6 | 1.34 | 0.21 | 2.365 | 6.20 | 67480 | 68270 | 66990 | 1280 | 1.90 |
| *10 | 1550 | 2 | 1.84 | 0.14 | 2.900 | 6.21 | 66530 | 67350 | 65950 | 1400 | 2.10 |
| *11 | 1550 | 4 | 1.79 | 0.18 | 2.370 | 6.18 | 65520 | 66370 | 63950 | 2420 | 3.69 |
| 12 | 1550 | 6 | 1.41 | 0.13 | 2.371 | 6.17 | 67950 | 68450 | 67400 | 1050 | 1.55 |

### 2. Evaluation of Dielectric Sintered Body

### (1) Evaluation of Peak Intensity Ratio A

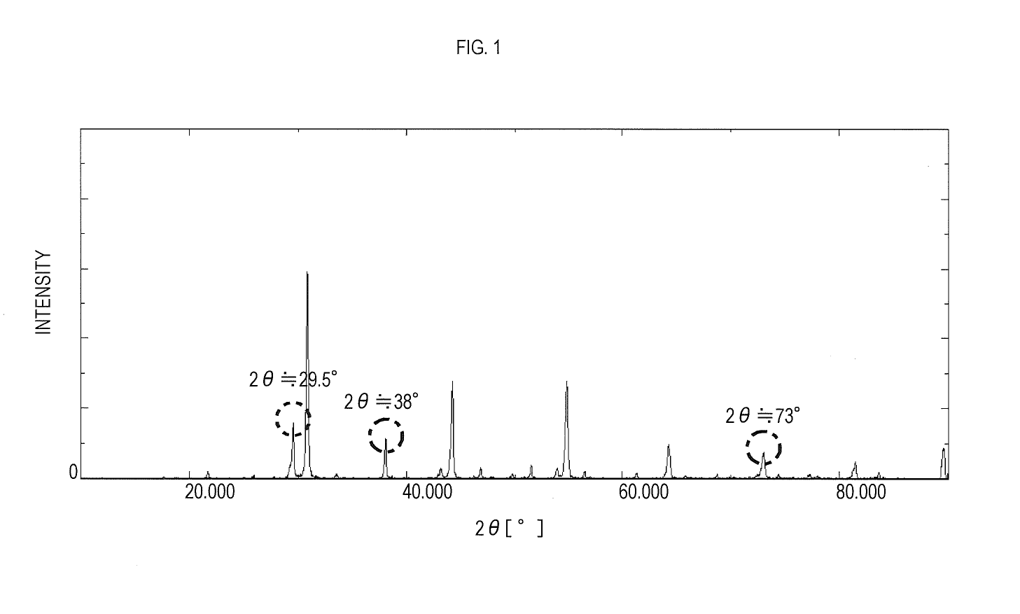

An X-ray diffraction measurement was performed for each of the dielectric sintered bodies produced. FIG. 1 represents an example of the X-ray diffraction measurement result. In the X-ray diffraction measurement result, the peak intensity p1 for the peak of the (310) plane (in the vicinity of 2θ=73°, and the peak intensity p2 for the peak of the (111) plane (in the vicinity of 2θ=38°) were calculated. Moreover, the peak intensity ratio A (p2/p1) of the peak intensity p2 to the peak intensity p1 was calculated. The calculated peak intensity ratios A are presented in Table 1. Here, the peak intensity means the peak height.

### (2) Measurement of Specific Gravity B

The specific gravity B of each dielectric sintered body produced was measured by using the Archimedean method. The results are presented in Table 1.

### (3) Measurement of Half Bandwidth C

In the X-ray diffraction measurement result, the half bandwidth C of the peak of the (111) plane (in the vicinity of 2θ=38°; the peak with the peak intensity p2) was measured. The half bandwidth C is the width of the peak in a part where the intensity (height) is half the maximum value. The unit of half bandwidth is degree.

(4) Measurement of d-value D

The d-value D of the peak of the (111) plane (in the vicinity of 2θ=38°; the peak with the peak intensity p2) of each dielectric sintered body produced was measured. The d-value D means the spacing between the atomic lattice planes according to the Bragg condition. Namely, the d-value D corresponds to d according to the Bragg condition, as follows.

2d sin θ=nλ,

where θ is the angle between the atomic lattice planes and the X-ray, λ is the wavelength of the X-ray, and n is an integer.

The d-value D can be obtained by X-ray diffraction measurement. In the present embodiment, a Cu tube was used as the X-ray tube in the X-ray diffraction measurement, and Cu-Kα1 rays (wavelength: 1.5405 Å) were used.

(5) Measurement of f×Q Value

Each dielectric sintered body produced was ground into a cylindrical shape having an outer diameter of 34 mm, an inner diameter of 19 mm, and a thickness of 14 mm to prepare a measurement sample. The measurement sample was measured for resonant frequency f and Q value in the TE₀₁δ mode by using a dielectric resonator method. The “mean value”, the “maximum value”, the “minimum value”, the “maximum value−minimum value”, and the “variation” of the f×Q values (n=6) calculated from the measured f and Q values are presented in Table 1. The variation is defined by the following formula, and the unit is percent.

Variation=100*((maximum value)−(minimum value))/mean value

### 6) Measurement Results

The f×Q value was high and the variation was small in dielectric sintered bodies in which the peak intensity ratio A was from 0.9 to 1.5, the half bandwidth C was from 0.12 to 0.22°, and the d-value D was from 2.363 to 2.371. On the other hand, the f×Q value was low or the variation was large in dielectric sintered bodies in which the peak intensity ratio A, the half bandwidth C, and the d-value D fell outside of these ranges.

The specific gravity B was 6.2 or less, or 6.25 or more in dielectric sintered bodies that had a peak intensity ratio A of from 0.9 to 1.5. Such dielectric sintered bodies had high f×Q values, and the variation was small. Note that the specific gravity B had the tendency to increase as the sintering temperature of the sintering was decreased. Further, the specific gravity B had the tendency to decrease as the hold time of the sintering was increased. The resonant frequency f was measured to be about 1.8 GHz.

In Table 1 and in Table 2 below, the serial numbers appended with * represent examples that fall outside of the ranges of the present invention.

### Embodiment 2

Dielectric sintered bodies were produced and evaluated in basically a similar manner as in Embodiment 1. However, in Example 2, v=0.35 or 0.50 in the specific composition formula representing the K, Ba, Nb, Ta, Zn, and Co composition.

The sintering temperatures and the hold times of the sintering, and the evaluation results for the dielectric sintered bodies of Embodiment 2 are presented in Table 2.

TABLE 2

| | Composition | Sintering | Hold time | Intensity | Half bandwidth | d-Value D | Specific | f × Q value |
|---|---|---|---|---|---|---|---|---|
| No. | v = | temperature (° C.) | (hr) | ratio A | C (°) | (Å) | Gravity B | (GHz) |
| 13 | 0.35 | 1510 | 4 | 1.14 | 0.17 | 2.367 | 6.18 | 69092 |
| *14 | | 1550 | 2 | 0.85 | 0.20 | 2.362 | 6.16 | 48401 |
| *15 | | 1550 | 3 | 1.62 | 0.13 | 2.369 | 6.13 | 32733 |
| *16 | | 1550 | 4 | 2.23 | 0.13 | 2.369 | 6.14 | 30041 |
| *17 | | 1550 | 5 | 0.80 | 0.06 | 2.370 | 6.16 | 25866 |
| *18 | | 1550 | 6 | 1.06 | 0.14 | 2.362 | 6.13 | 30984 |
| *19 | | 1550 | 8 | 1.78 | 0.11 | 2.362 | 6.17 | 5242 |
| *20 | 0.50 | 1490 | 3 | 1.09 | 0.11 | 2.364 | 6.24 | 66523 |
| 21 | | 1520 | 3 | 1.15 | 0.19 | 2.368 | 6.20 | 68747 |
| 22 | | 1520 | 4 | 1.23 | 0.15 | 2.363 | 6.25 | 69138 |
| *23 | | 1535 | 4 | 0.96 | 0.15 | 2.362 | 6.19 | 66848 |
| *24 | | 1550 | 3 | 0.93 | 0.08 | 2.366 | 6.18 | 64183 |
| *25 | | 1550 | 4 | 3.51 | 0.13 | 2.371 | 6.18 | 65640 |

As in Embodiment 1, the f×Q value was high and the variation was small in dielectric sintered bodies in which the peak intensity ratio A was from 0.9 to 1.5, the half bandwidth C was from 0.12 to 0.22°, and the d-value D was from 2.363 to 2.371. On the other hand, the f×Q value was low or the variation was large in dielectric sintered bodies in which the peak intensity ratio A, the half bandwidth C, and the d-value D fell outside of these ranges.

Note that the specific gravity B had the tendency to increase as the sintering temperature of the sintering was decreased. Further, the specific gravity B had the tendency to decrease as the hold time of the sintering was increased. The resonant frequency f was measured to be about 1.8 GHz.

### Embodiment 3

Dielectric sintered bodies were produced and evaluated in basically a similar manner as in Embodiment 1. However, in Example 3, v=0.50 in the specific composition formula representing the K, Ba, Nb, Ta, Zn, and Co composition. The amounts of the water and the binder added to the powder after the calcination were 40 weight parts and 2 weight parts, respectively, with respect to 100 weight parts of the powder after the calcination. The amount of the zirconium oxide added to the powder after the calcination was 0 weight part, 0.1 weight parts, 0.2 weight parts, 0.3 weight parts, or 0.5 weight parts with respect to 100 weight parts of the powder after the calcination. The dielectric sintered bodies were produced with these five different amounts of zirconium oxide.

Table 3 presents the sintering temperature and the hold time of the sintering, and the evaluation results for the dielectric sintered bodies of Embodiment 3. Though omitted in Table 3, the dielectric sintered bodies had peak intensity ratios A of from 0.9 to 1.5, half bandwidths C of 0.12 to 0.22°, and d-values D of 2.363 to 2.371.

TABLE 3

| | | Amount of | Sintering | | | |
|---|---|---|---|---|---|---|
| | Composition | ZrO₂ added | temperature | Hold time | Specific | f × Q value |
| No. | v = | (wt %) | (° C.) | (hr) | Gravity B | (GHz) |
| 26 | 0.50 | 0 | 1520 | 4 | 6.30 | 65404 |
| 27 | | 0.1 | | | 6.27 | 69423 |
| 28 | | 0.2 | | | 6.27 | 68171 |
| 29 | | 0.3 | | | 6.27 | 63037 |
| 30 | | 0.5 | | | 6.21 | 8330 |

Q value further improved in experiment examples in which ZrO₂ was contained in less than 0.3 wt %, as compared with the experiment example in which ZrO₂ was not contained. However, Q value had the tendency to decrease when ZrO₂ was added in 0.3 wt % or more, as compared with the samples that contained less than 0.3 wt % of ZrO₂. Q value prominently decreased particularly when ZrO₂ was added in 0.5 wt %. It can be speculated that ZrO₂ exists in the spacing between the crystal grain boundary planes. It can be speculated that, without addition of ZrO₂, the Q value relatively decreases as a result of the failure to close the crystal grain spacing. It can also be speculated that, with the excess addition of ZrO₂, the crystal grain spacing widens and causes the substances to segregate, with the result that the Q value decreases. Further, the excess addition of ZrO₂ increases holes, and lowers the specific gravity of the dielectric sintered body.

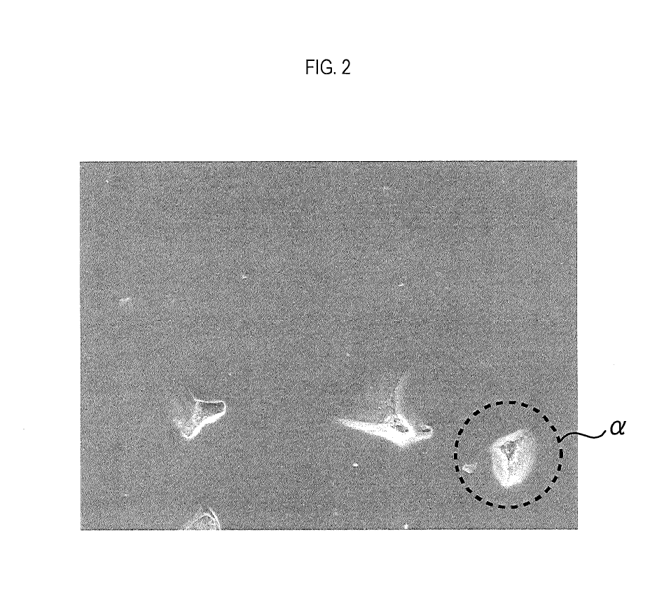

The dielectric sintered body No. 30 (ZrO₂ content of 0.5 wt %) in Table 3 was observed with a SEM (scanning electron microscope). The dielectric sintered body No. 30 was also examined for its surface element distribution, using an EDS (energy dispersive X-ray analyzer). The SEM image is shown in FIG. 2. A hole portion α can be confirmed in the SEM image. The grain boundary plane is largely exposed in the hole portion α. In an EDS analysis, Zr was detected more strongly in the hole portion α (grain boundary plane) than in the other regions. Nb was more weakly detected in the hole portion α (grain boundary plane) than in the other regions. These results confirmed that the zirconium oxide (eccentrically) exists at the crystal grain boundary plane, and closes the grain boundary spacing. The analysis of the dielectric sintered body No. 27 (ZrO₂ content of 0.1 wt %) in Table 3 yielded the same result as that for the dielectric sintered body NO. 30.

Note that the presence of the zirconium oxide at the crystal grain boundary plane makes it possible to move the substances with less heat quantity, and to easily precipitate the Ba₅Nb₄O₁₅ crystalline phase (a superlattice structure can be obtained more easily). As the result, higher Q values can be obtained.

### Experiment Example

A dielectric sintered body was produced in basically a similar manner as for the dielectric sintered body No. 30 of Embodiment 3. However, in this Experiment Example, the zirconium oxide was added at a different timing. Namely, the zirconium oxide was added when milling and mixing the barium carbonate, zinc oxide, cobalt oxide, niobium oxide, potassium carbonate, and tantalum oxide (before the calcination), instead of being added after the calcination.

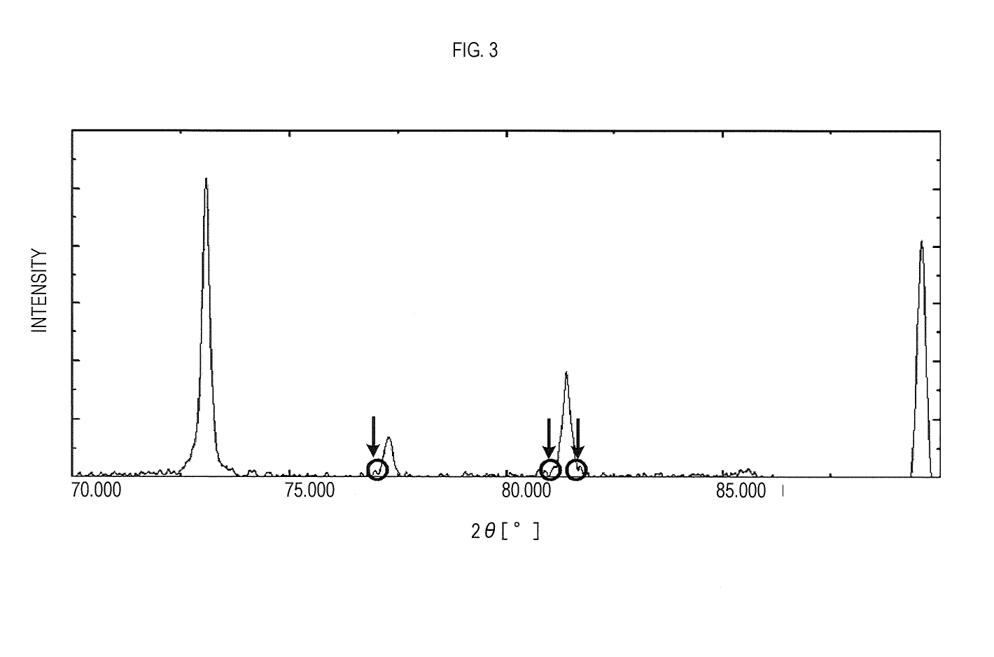

The dielectric sintered bodies produced as above were subjected to X-ray diffraction measurement. The X-ray diffraction measurement result is presented in FIG. 3. In FIG. 3, the peaks (2θ≈77.0°, 81.5°, 81.7°) indicated with open circles were more strongly detected than in the measurement results shown in FIG. 1 (measurement results for the dielectric sintered bodies produced by adding zirconium oxide after the calcination). Conceivably, the peaks with open circles in FIG. 3 are due to the composition shift caused by the reaction of Zr and Nb during the calcination. The composition shift causes the Q value to decrease.

It should be noted that the present invention is in no way limited by the foregoing Embodiments, and various embodiments are possible without departing from the spirit of the present invention. For example, the K, Ba, Nb, Ta, Zn, and Co composition in the dielectric sintered body may be set in any way within the ranges that satisfy the composition formula ((100−a)[Baᵤ{(ZnᵥCo₁₋ᵥ)_{w}Nbₓ}O_{δ1}]−a[K_{y}Ta_{z}O_{δ2}]) (0.5≦a≦25, 0.98≦u≦1.03, 0≦v≦1, 0.274≦w≦0.374, 0.646≦x≦0.696, 0.5≦y≦2.5, 0.8≦z≦1.2). Even in this case, the peak intensity ratio A can easily be set to any value in the 0.9 to 1.5 range by adjusting the sintering temperature and/or the hold time of the sintering.

The specific gravity B also can be adjusted within the range of 6.2 or less, or 6.25 or more, by adjusting the sintering temperature and/or the hold time of the sintering.

Further, when producing the dielectric sintered body, only the zirconium oxide may be added to the powder after the calcination, without adding water and the binder. Molding is also possible in this case by using known techniques.

When the dielectric sintered body is configured without including K and Ta, X-ray diffraction measurement yields the same result as when K and Ta are included. However, ease of sintering is not as desirable as when K and Ta are included. Moreover, the dielectric sintered body configured to include K and Ta has a higher Q value than a dielectric sintered body configured without including these elements.

1. A dielectric sintered body, comprising:
Ba, Nb, and at least one of Zn and Co, as main components; and
K and Ta as subcomponents;
having a ratio A of a peak intensity p2 of a (111) plane peak to a peak intensity p1 of a (310) plane peak in an X-ray diffraction measurement being 0.9 to 1.5,
having a half bandwidth C of the (111) plane peak ranging from 0.12 to 0.22°,
having a d-value D of the (111) plane peak ranging from 2.363 to 2.371, and having a Perovskite structure.

2. The dielectric sintered body as claimed in claim 1, wherein the dielectric sintered body includes a Ba₅Nb₄O₁₅ crystalline phase.

3. The dielectric sintered body as claimed in claim 1, wherein the dielectric sintered body further comprises zirconium oxide.

4. The dielectric sintered body as claimed in claim 3, wherein the zirconium oxide comprises less than 0.3 wt %.

5. The dielectric sintered body as claimed in claim 3, wherein the zirconium oxide exists at a crystal grain boundary plane.

6. The dielectric sintered body as claimed in claim 1,
wherein the dielectric sintered body contains K, Ba, Nb, and Ta, and at least one of Zn and Co as constituting elements, and
wherein a composition ratio of the constituting elements substantially satisfies the composition formula:
(100−a)[Baᵤ{(ZnᵥCo₁₋ᵥ)_{w}Nbₓ}O_{δ1}]−a[K_{y}Ta_{z}O_{δ2}] (0.5≦a≦25, 0.98≦u≦1.03, 0≦v≦1, 0.274≦w≦0.374, 0.646≦x≦0.696, 0.5≦y≦2.5, 0.8≦z≦1.2).

7. A method for manufacturing the dielectric sintered body as claimed in claim 1,
the method comprising adding zirconium oxide after calcining a raw material, followed by performing sintering.

8. A dielectric resonator produced from the dielectric sintered body as claimed in claim 1.
